(19) United States
(12) Patent Application Publication
(10) Pub. No.: US 2022/0165547 A1
(43) Pub. Date: May 26, 2022

(54) NOVEL AND EFFECTIVE HOMOGENIZE FLOW MIXING DESIGN

(71) Applicant: Applied Materials, Inc., Santa Clara, CA (US)

(72) Inventors: Vishwas Kumar PANDEY, Madhya Pradesh (IN); Eric Kihara SHONO, San Mateo, CA (US); Christopher S. OLSEN, Fremont, CA (US); Tobin KAUFMAN-OSBORN, Sunnyvale, CA (US); Erika HANSEN, San Jose, CA (US); Rene GEORGE, San Carlos, CA (US); Lara HAWRYLCHAK, Gilroy, CA (US); Hansel LO, San Jose, CA (US); Kartik Bhupendra SHAH, Saratoga, CA (US)

(21) Appl. No.: 17/103,697

(22) Filed: Nov. 24, 2020

(51) Int. Cl. H01J 37/32; H01L 21/67; C23C 16/50; C23C 16/455

(52) U.S. Cl. CPC H01J 37/32449; H01L 21/67069; H01J 2237/334; C23C 16/455; H01J 2237/332; C23C 16/50

(57) ABSTRACT

Provided herein is a gas source comprising a flow conduit having an interior volume and an open end, a remote plasma source fluidly coupled to the flow conduit, a secondary gas source extending inwardly of the interior volume of the flow conduit, the secondary gas source including at least one gas port therein positioned to flow a secondary gas inwardly of the interior volume of the flow conduit.

### BACKGROUND

### Field

The present disclosure generally relates to thin film materials, in particular the deposition, modification, or removal of thin film materials on a substrate, using two or more gas precursors. More particularly, the present disclosure relates to the homogenized mixing of two or more gaseous flow streams, at least one of which having passed through an activation device before reaching the substrate for better on-substrate results, here, greater uniformity of the reaction across the surface of the substrate.

### Description of the Related Art

The deposition of, modification of, or removal of materials from a substrate may require the use of two or more precursor gases which need to be in a homogenous mixture when they react with a surface of a substrate. In some deposition, modification or removal processes, one or more of these gases is desirably activated, i.e., radicals of the precursor gas are introduced to the surface of the substrate or a material thereon for reaction therewith. One method of activation is to flow a gaseous precursor form a gas source, through a remote plasma source to activate at least a portion of the gas atoms or molecules passing through the remote plasma source into radicals of the gas atoms or molecules, and flowing those radicals into a substrate processing chamber where the radicals reach, and react with, the substrate or a material thereon.

However, the flow capacity of a remote plasma source to flow a gas therethrough and convert at least part of that flow into radicals is limited. This limits the flexibility of a system using a remote plasma source, in particular for processes where the percentage or concentration of the species which must be activated need be varied, or where a high gas flow rate is desirable to decrease the process time, because the activated gas is highly diluted with a second gas, for example a gas which is used to dilute the flow of the activated species to reduce the reaction rate of the activated precursor with the surface of the substrate. For example, where nitriding of a substrate surface, or a film layer on the substrate is required, nitrogen and a diluent gas, for example hydrogen, are flowed through the remote plasma source, whereby the hydrogen is intended as a diluent and not a significant reactant on the substrate or film surface. Likewise, where oxidizing of a substrate surface, or a film layer on the substrate is required, oxygen and a diluent gas, for example hydrogen, are flowed through the remote plasma source However, at high flow rates of highly diluted primary gas, it has been found that particulates are formed and emitted from the remote plasma source, which can reach, and contaminate, the substrate surface.

### SUMMARY

In one aspect, a gas source is provided, comprising a flow conduit having an interior volume and an open end, a remote plasma source fluidly coupled to the flow conduit, a secondary gas source extending inwardly of the interior volume of the flow conduit, the secondary gas source including at least one gas port therein positioned to flow a secondary gas inwardly of the interior volume of the flow conduit. The flow conduit includes an expanding portion interposed between the remote plasma source and the open end thereof, an expanding portion interposed between the location of the secondary gas source inwardly of the interior volume of the flow conduit and the open end thereof, and a secondary gas source comprises a conduit extending inwardly of the interior volume of the flow conduit.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a sectional view of a substrate processing chamber for holding a substrate during processing thereof

FIG. 2 is an isometric view of the processing chamber of FIG. 1 connected to a remote plasma source (RPS) through an inlet, and chamber exhaust.

FIG. 3 is a plan view of the process chamber of FIG. 3.

FIG. 4 is a sectional view of a portion of the inlet of FIG. 2 at 4-4.

FIG. 5 is a sectional view a portion of the inlet of FIG. 2 at 5-5.

FIG. 6 is a partial sectional view of a portion of the inlet having a post RPS injector extending inwardly thereof.

FIG. 7 is a partial sectional view of a portion of the inlet having an additional different version of a post RPS injector extending inwardly thereof.

FIG. 8 is a partial sectional view of a portion of the inlet having another additional version of a post RPS injector extending inwardly thereof.

FIG. 9 is a partial sectional view of a portion of the inlet having another additional version of a post RPS injector extending inwardly thereof.

FIG. 10 is a partial sectional view of a portion of the inlet having another additional version of a post RPS injector extending inwardly thereof.

FIG. 11 is a sectional view of a portion of the inlet, showing pairs of dual post rps injectors extending inwardly thereof.

FIG. 12 is a gas presence view of the gas passages within an injector, showing the location of the gas within the injector with the wall surfaces thereof removed, to better show the multiple outlets thereof t.

FIG. 13 is a sectional view of the curved post RPS injector extending inwardly of the inlet.

FIG. 14A is a gas presence view of the gas passages within an injector, showing the location of the gas within the injector with the wall surfaces thereof removed, to better show the multiple outlets thereof.

FIG. 14B is an isometric view of the post RPS injector of FIG. 14A with multiple inlets extending inwardly of the inlet.

FIG. 15A is a gas presence view of the gas passages within an injector, showing the location of the gas within the injector with the wall surfaces thereof removed, to better show the multiple outlets thereof lets.

FIG. 15B is an isometric view of the post RPS injector of FIG. 15A with multiple inlets extending inwardly of the inlet.

FIG. 16 is an isometric view of the side of a chamber having a manifold connected to the sidewall thereof, showing the connection components for attaching a nozzle to the manifold to inject a gas thereinto in an exploded view.

FIG. 17 is a sectional view of the isometric view of the side of a chamber having a manifold connected to the sidewall thereof, showing the connection components for attaching a nozzle to the manifold to inject a gas thereinto in section.

FIG. 18 is an enlarged view of the connection components for attaching a nozzle to the manifold to inject a gas thereinto in section.

FIG. 19 is a schematic sectional view of a substrate processing chamber for holding a substrate during processing thereof, and having a manifold connected to the topwall thereof, the manifold having a nozzle connected therein to inject a gas thereinto and through a perforated plate, also known as a showerhead, before reaching the substrate.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to process and apparatus for performing a thin film process on a substrate, for example, treatment of the surface of the substrate or discrete portions thereof, treatment of a thin film layer formed on the substrate or discrete portions of that thin film, and treatment of all or portions of three dimensional structures formed on or into a substrate, as well as etching or depositing of film layers with respect to the surface of a substrate. Herein, a substrate processing chamber is provided for holding a substrate therein in a desired environment, including a vacuum environment, and a remote plasma source is ported to the chamber to provide an activated first gaseous atomic or chemical species capable of reacting with a surface of the substrate, a film layer formed thereon, or a feature on or extending into the substrate or film layer. To properly process the substrate, film layer, or feature on or extending into the substrate, it can be desirable to modulate the concentration of the activated gas species with respect to a non-reactive diluent, for example hydrogen when the first species is or includes oxygen, including oxygen radicals, and the nitrogen radicals are used to react with, and convert, an exposed surface of a silicon layer into a silicon-nitrogen layer, while not reacting with other materials on the substrate. For example, in 3D memory applications, stacks of alternate layers of silicon nitride and silicon oxide may need be formed. Where a silicon layer is present between adjacent silicon nitride layers, the radical oxygen species can be used to convert a portion of the silicon layer, at the outer surface thereof and extending inwardly form the outer surface thereof, into silicon oxide. Likewise, there may arise a need for converting the material at the bottom of a high aspect ratio trench, via or contact into a compound, or a different compound, by incorporating the first species therein. In such a case, the radical first species, for example radicals of oxygen atoms flowing through the remote plasma source can be used to convert this material into an oxidized version of the chemical species of the layer, or radicals of nitrogen atoms flowing through the remote plasma source can be used to convert this material into an nitrided version of the chemical species of the layer, among other gases that can be converted to radicals.

The concentration of radical reactant species is in one aspect modulated to effect or modify the reaction rate of the base material with the activated reactant species measured with respect to time, for example to slowly grow or form a silicon oxide layer on exposed silicon for example, where too rapid a reaction may cause growth of the oxidizing material layer into the opening in which the material to be oxidized is exposed, and thereby blocking access of the radicals of the first species to locations further inwardly of the opening which likewise need to be reacted with by the radicals of the activated gas species. Here, to controllably modulate the concentration of the radical species in the overall volumetric flow of gasses entering the process chamber, a second gas source is located downstream of the remote plasma source, and a second gas is introduced through the second gas source into the flow of the energized first gas, and the flow quantity of the second gas and the flow quantity of the first gas to form reactant radicals flowing through the remote plasma source are both variably controllable to allow concentrations of the first, energized, gas to the total gas volume entering the chamber to be between 0 and 100%. Here, the first, energized, gas is the species passing through the remote plasma generator, it being understood in the art that the amount of that gas converted into radicals in the remote plasma generator is typically less than 100%, and thus both base (non-activated into radical) species and activated radical species of the gas passing through the remote plasma generator make up the energized or activated first gas flow volume.

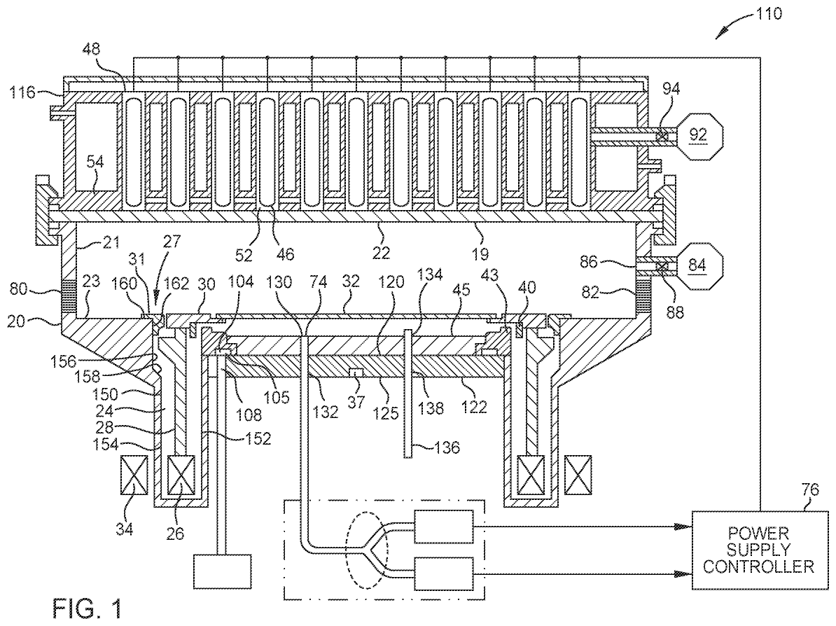

FIG. 1 is a cross-sectional view of an exemplary processing chamber, here process chamber 110, for example here a rapid thermal processing or “RTP” type of process chamber 110, useful to securely hold a substrate for processing in a gaseous environment according to examples of the present disclosure. Process chamber 110 is configured to receive a substrate 32 therein, and rotate the substrate 32 while receiving energy into the process chamber 110 to heat the substrate 32 to an elevated temperature, the elevated temperature of the substrate resulting in a faster reaction rate of the reactant species introduced into the chamber with the substrate or a portion thereof, including all of, or portions of a film layer thereon or a structure thereon or extending thereinto. Here, the processing chamber 110 is configured to rotate the substrate 32 about a center point, for example the center of a rotor 26 coupled to a substrate support, 28 supporting the substrate 32 thereon, to allow even heating of the substrate 32 by the energy source of the processing chamber.

The processing chamber 110 includes a chamber body 20 having a first portion 21 and a second portion 23, and an electromagnetic energy transparent window, here window 22 disposed on the first portion 21 of the chamber body 20. A lamp assembly 16 is disposed over the window 22. The lamp assembly 16 includes a housing 54. A plurality of lamps 46 are disposed in the housing 54, and each lamp 46 is disposed within a corresponding opening 52 in the housing 54. The lamps 46 are connected to a power supply controller 76 via a plurality of electrical sockets, one socket 48 for each lamp 46. During operation, the lamps 46 emit radiation through the window 22 toward a substrate 32 disposed in the process chamber 110 to heat the substrate to a predetermined temperature. The predetermined temperature may range from about 20° C. to about 1,500° C. The window 22 is generally made of any material resistant to the processing environment, which maintains rigidity when exposed to the facing substrate at the elevated temperature, and transmissive to the desired radiation. For example, quartz is typically used for the window 22 since quartz is transparent to infrared light emitted by the lamps 46 and absorbed by the substrate. Other suitable window 22 materials include, but are not limited to, sapphire. In further examples, the window 22 is optionally coated with an anti-reflective coating or suitable electromagnetic energy filters, present on one or both sides of the window 22. For example, optional ultra-violet (UV) filters are used to avoid generation of ions and radicals in the chamber from the electromagnetic energy spectrum of the lamps 46 or damage to UV-sensitive structures on the substrate 32, if the lamps 46 have significant UV output. As another example, optional notch filters are used to admit narrow band radiation. In some embodiments, a filter 19 is coated on an inside surface of the window 22, as shown in FIG. 1A The filter 19 blocks radiation having wavelengths within a specific range, such as between about 780 nm and about 880 nm, while transmitting radiation having wavelengths outside of the specific range. The filter 19 may be a plurality of alternating layers, such as oxide layers. In one embodiment, the filter 19 includes alternating silicon dioxide layers and titanium dioxide layers, and silicon dioxide layers are located at opposite ends of the filter. In one embodiment, the filter 19 includes a total of 30 to 50 alternating layers. The filter 19 may be coated on an outside surface (facing the lamp assembly 16) of the window 22, an inside surface (facing the substrate support) of the window 22, or may be embedded in the window 22.

An inlet port 80 and an outlet port 82 are formed in the first portion 21 of the chamber body 20. During operation, the pressure within the process chamber 110 can be reduced to a sub-atmospheric pressure prior to introducing a process gas through the inlet port 80. A vacuum pump 84 shown schematically evacuates the process chamber 110 by pumping gas from the interior of the process chamber 110 through an exhaust port 86 formed in the first portion 21 of the chamber body 20. A valve 88 disposed between the exhaust port 86 and the vacuum pump 84 is utilized to control the pressure within the process chamber 110. A second vacuum pump 90 shown schematically is connected to the lamp assembly 16 to reduce the pressure within the lamp assembly 16, particularly when the pressure within the process chamber 110 is pumped to a reduced pressure to reduce the pressure differential across the window 22. The pressure within the lamp assembly 16 is controlled by a valve 94.

An annular channel, here channel 24 is formed in the chamber body 20, and a rotor 26 is disposed in the channel 24. The channel 24 is located adjacent the second portion 23 of the chamber body 20. The process chamber 110 further includes a rotatable substrate support 28 disposed in the channel 24, a substrate edge support 30 disposed on the rotatable substrate support 28, and a shield 27 disposed on the second portion 23 of the chamber body 20. The rotatable substrate support 28 is fabricated from a material having high heat resistivity, such as black quartz. In one embodiment, the rotatable substrate support 28 is a cylinder. In one embodiment, the substrate edge support 30 is an edge ring. The channel 24 has an outer wall 150 and an inner wall 152. A lower first portion 154 of the outer wall 150 has a first radius and an upper second portion 156 of the outer wall 150 has a second radius greater than the first radius. A third portion 158 of the outer wall 150 connecting the first portion 154 to the upper second portion 156 extends linearly from the first portion 154 to the upper second portion 156, forming a slanted surface that faces toward the substrate edge support 30. The shield 27 has a first portion 160 that rests on the second portion 23 of the chamber body 20 and a second portion 162 that extends into the channel 24 along the upper second portion 156 of the outer wall 150. The first portion 160 contacts the chamber body 20, and the second portion 162 contacts the outer wall 150. The shield 27 extends partially over the channel 24. In one embodiment, the shield 27 is a rotor cover. The shield 27 may be an annular ring. The shield 27 may be fabricated from a ceramic material, such as alumina. The shield 27 further includes a first surface 31 facing the window 22, and the first surface 31 is substantially flat so radiant energy is not reflected towards the substrate 32. The substantially flat first surface 31 does not face the substrate processing area to avoid reflecting radiation toward the substrate 32. In one embodiment, the first surface 31 of the shield 27 is substantially parallel to the window 22. In one embodiment, the first surface 31 is annular.

The substrate 32, such as a silicon substrate, is disposed on the substrate edge support 30 during operation. A stator 34 is located external to the chamber body 20 in a position axially aligned with the rotor 26. In one embodiment, the stator 34 is a magnetic stator, and the rotor 26 is a magnetic rotor. During operation, the rotor 26 rotates, which in turn rotates the rotatable substrate support 28, the substrate edge support 30, and the substrate 32 supported thereon.

During operations in which the substrate 32 is heated to a relatively low temperature, such as from about 20° C. to about 350° C., the substrate edge support 30 can retain heat that can cause the temperature at the edge of the substrate 32 to be higher than the temperature at the center of the substrate 32. In order to cool the substrate edge support 30, a cooling member 43 is disposed on the chamber body 25 and is in proximity to the substrate edge support 30. The chamber body 25 includes a first surface 120 and a second surface 122 opposite the first surface 120. The cooling member 43 is in direct contact with the first surface 120 of the chamber body 25. A thickness of the substrate edge support 30 may be over-specified to provide extra thermal mass. Such an edge support can act as a heat sink, which helps avoid overheating at the edge of the substrate 32. In one embodiment, a feature 40, such as a fin, is formed on the substrate edge support 30 to provide extra thermal mass. The feature 40 may be continuous or discontinuous. In one embodiment, the feature 40 is cylindrical. The feature 40 may be a plurality of discrete fins. The feature 40 may be formed on a surface of the substrate edge support 30 that is facing the channel 24. In one embodiment, the feature 40 extends into the channel 24, as shown in FIG. 1. In some embodiments, the feature 40 is formed on a surface of the substrate edge support 30 that is facing the window 22. The feature 40 is substantially perpendicular to a major surface of the substrate edge support 30. In some embodiments, the feature 40 extends obliquely from the major surface of the substrate edge support 30.

The chamber base of the chamber body 25 includes a channel 37 formed therein for a coolant to flow therethrough. In one embodiment, the coolant is water. The cooling member 43 may be fabricated from a material having high heat conductivity, such as a metal, for example, aluminum. The cooling member 43 is cooled by the base of the chamber body 25 and functions as a heat sink to the substrate edge support 30 due to the close proximity to the substrate edge support 30. Furthermore, the cooling member 43 includes a recess 104 formed in a surface that is in contact with the first surface 120 of the base of the chamber body 25.

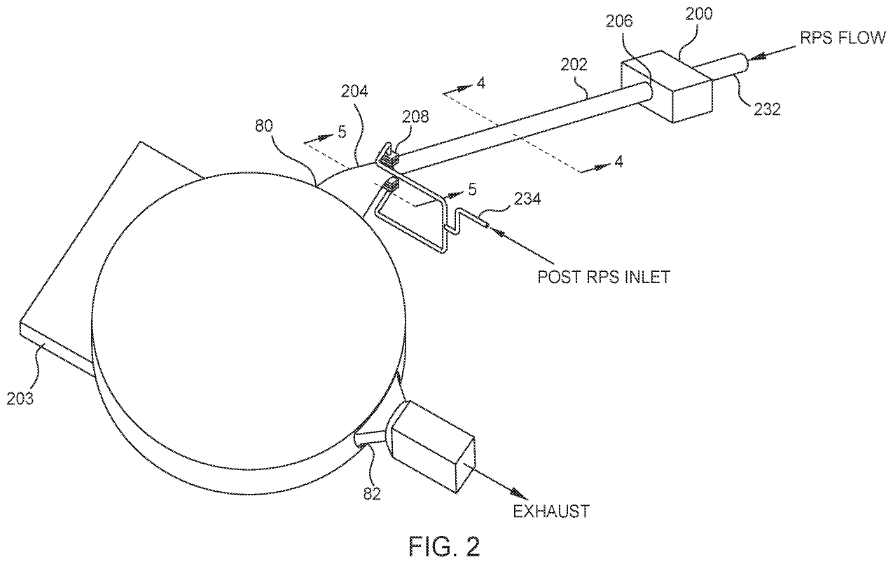

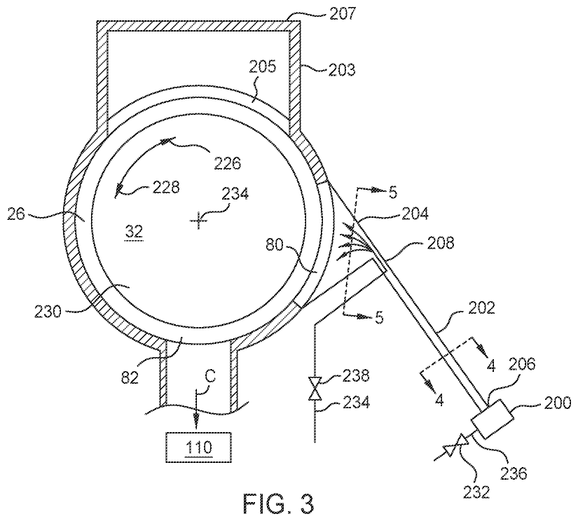

FIG. 2 is a schematic isometric view of the process chamber 110 according to examples of the present disclosure, showing the process volume of the process chamber 110 with the lamp assembly 16 removed, and FIG. 3 is a plan view of the process chamber 110 with the lamp assembly 16 removed. Here, a slit valve 203 is provided and opens into the chamber body 20 through an opening 205 in the outer wall thereof at a location thereon facing the outlet port 82. The slit valve 203 allows a substrate 32 to be loaded into the process volume in the interior of the chamber body 20, and removed therefrom, by a robotic end effector (not shown), and a door 207 closes over and seals off the opening to allow the environment of the process volume to be independently controlled as compared to the environment exteriorly of the chamber body 20.

Process chamber 110 is useful for, among other things, treatment of substrates and film layers thereon, as well as deposition of film layers and removal of film layers, including selectively doing so, using radical species introduced thereinto using a remote plasma source or generator, such as remote plasma generator 200 as shown schematically in FIG. 2. It is known in the art to flow an inert gas, such as Argon, through a remote plasma source to initiate or maintain the plasma in the remote plasma generator 200. In some process applications an excited gas species including radicals of the underlying gas is generated by the remote plasma generator 200 and is passed into the process chamber 110 through a conduit, here first and second conduits 202, 204, and is used to interact with the substrate or a selected surface thereon for surface layer modification, etching of the surface of the substrate or a layer formed thereon, or deposition of a layer. The relative percentage of a first gas species, which is converted at least partially into radicals in the remote plasma generator 200, flowing into the total volume of gas in the process chamber 110, or in the total gas flow through the remote plasma generator 200, can be modified, or maintained at a specific percentage, during the processing of the substrate or a material layer thereon. In some process applications, the diluent species is itself a reactant, or it may react with surfaces of the remote plasma generator through which it is flowing. In some instances, over the range of desirable relative percentages of the first gas species at least partially converted to radicals in the remote plasma generator 200 and of a desired diluent or second gas species, the combined gas species are non-reactive with the surfaces of the remote plasma generator over a portion of the range of desirable relative percentages, but reactive with these surfaces in other desirable portions of the range of desirable relative percentages.

To enable a full, desirable, range of relative percentages of the different species and activated radicals of one or more species in the flow of gases into the process chamber 110, a first injector 220 (FIG. 6), having a generally tubular outer surface, at least one central gas flow passage 221 extending thereinto and connected at one end thereof to a source of a second gas, and at least one of the gas injection openings 222 fluidly coupling the central gas flow passage 221 to the exterior of the first injector 220, is provided, such that the opening opens into the flow of a first activated gas, including activated or radical species of the first gas passing from the remote plasma generator, at a location between the remote plasma generator 200 and the process volume within the process chamber 110. The second gas, flowing outwardly of the gas injection opening 222, is injected into the flow of the first gas at a location, in a direction parallel to, transverse to, or both parallel and transverse to the flow direction of the first gas, downstream of the remote plasma generator 200 and upstream of the interior process volume of the process chamber 110, to intermix therewith to form a sufficiently uniform and homogeneous mixture of the first and second gases when the combined flow thereof reaches a substrate 32 in the process volume region of the process chamber 110 to perform a process on the substrate 32, which mixture is sufficiently uniform over the surface thereof, i.e., from location to location over the surface of the substrate 32 or a material thereon or therein.

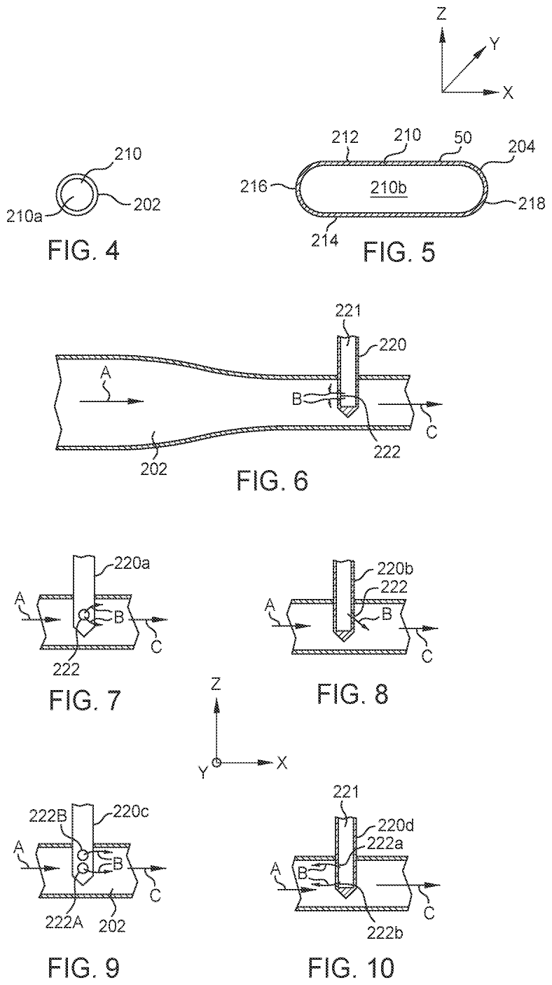

Referring to FIG. 2, to provide activated chemical species, i.e., a first gas precursor having at least a portion thereof activated as radicals, i.e., being in a radical state, the remote plasma generator 200 is connected to the process volume of the process chamber 110 at the inlet port 80 via the first conduit 202 and the second conduit 204, wherein the first conduit 202 is a generally right annular piping having a generally circular internal cross section connected at a first end 206 thereof to the remote plasma generator 200 and at a second end 208 thereof to the second conduit 204. Second conduit 204 is here configured as an annular walled flow expander or manifold, whereby the interior flow cross section 210 thereof increases from the connection thereof with the second end 208 of the first conduit 202 to the connection thereof with the interior process volume of the process chamber 110 at the inlet port 80. Here, this expanding interior flow cross section 210 has, at the fluid connection thereof with the first conduit, a generally circular cross section 210a as shown in FIG. 4, which expands into an ovoid or partially elliptical cross section 210b, bounded by opposed upper and lower generally planar, and parallel to each other, upper and lower walls 212, 214, and opposed curved side walls 216, 218 joining to the opposed upper and lower walls 212, 214 at opposed curved end walls thereof as shown in FIG. 5.

To provide the second gas species in this aspect, the single or first injector 220 is provided to extend inwardly of the first conduit 202 just inwardly thereof from the second end 208 thereof, and as shown in FIG. 6 includes therein a first, single, gas injection opening 222, in the aspect shown in FIG. 6, flowing the second gas as a flow shown by arrows B into the flow of the first, activated, gas shown as arrow A, the second gas initially directed by the gas injection opening in the direction directly upstream of the flow of the first gas A toward the process chamber 110, with the resultant mixed stream of the first and second gas then flowing in the direction of the second conduit 204 as shown by arrow C. This flow then mixes, and expands, in all three directions (the X, Y and Z directions) as it passes through the expanding cross section of the second conduit 204 as shown by arrows C in FIG. 3, and enters the process chamber 110 through the inlet port 80 to the process chamber 110.

The mixed flow of the first and second gasses (flow A and flow B forming mixed flow C) then flows over a substrate 32 supported on, and rotated about the center point 224 which of the rotor 26, in either a clockwise direction 226 or counterclockwise direction 228 (looking down on the rotor from the perspective of the lamp assembly 16), whereby the mixed flow of gasses C is distributed over the entire surface of the substrate 32. The substrate upper surface 230 is rotated, when supported on the rotor 26 and the rotor 26 is magnetically levitating and rotating about the center point 224 at an elevation with respect to the surface of the earth, which is slightly below the lower wall 214 of the second conduit, and the substrate 32 and lower wall 214 extend generally horizontally, and in parallel planes, to one another. Thus, as the mixed flow C of the first and second gasses flows inwardly of the process chamber 110 through the inlet port 80, it is injected inwardly from the inlet port 80 over the substrate upper surface 230, at least beyond the center point 224 of the rotor 26, and this gas introduction paradigm, in conjunction with the rotation of the substrate 32, causes the mixed flow C of the first and second gasses to reach all locations of the substrate upper surface 230 to react therewith.

The flow B of the second gas in the first conduit 202 in the direction upstream of the flow A of the first gas coming from the remote plasma generator 200 and then the combined flows of the first and second gasses flowing within the first conduit 202 in the direction C toward the inlet port 80 of the process chamber 110 helps ensure sufficient inter-mixing of the second gas with the first gas to ensure sufficient uniformity of the concentration of the first gas in the combined flow C of the first and second gas across the substrate upper surface 230 to enable uniform processing of the exposed surface thereof over the entire substrate upper surface 230. For example, where the substrate 32 includes regions of exposed silicon and regions of silicon nitride, activated oxygen is formed by the flow of oxygen through the remote plasma generator 200, such that oxygen in atomic form and oxygen radicals are emitted from the remote plasma generator 200 and flow in the first conduit toward the process chamber, to convert the exposed regions of silicon to silicon oxide while minimally reacting with the silicon nitride to form a silicon oxynitride. Additionally, it is desirable to control the reaction rate of the silicon oxide with the exposed silicon, for example where the exposed silicon in is a deep narrow, or high aspect ratio, feature. Here, the concentration of the activated species to the overall gas flow is desirably low, at least initially, and in some processes, it may be desirable to change that concentration as the reaction occurs or progresses. Therefore, here, the first gas is provided to the remote plasma generator 200 through first gas line 232 through a first flow modulation device 236, and the second gas is supplied to the first injector 220 through a second gas line 234 through a second flow modulation device 238. First and second flow modulation devices 236, 238, may be variable orifices, variable flow valves, mass flow controllers, or other such devices that allow variation in the flow rate of the gas species flowing therethrough. To change the concentration of the first gas in the total combined flow of the first and second gasses, or put differently, the ratio of the first gas to the second gas in the combined first and second gas mixture, the first, the second, or both the first and second flow modulation devices 236, 238 are controlled to vary the flow rate of the gas flows therethrough. To reduce the concentration of the first gas in the combined gas mixture, the first flow modulation device 236 can be controlled to reduce the flow rate of the first gas through the remote plasma generator 200 while maintaining the flow of the second gas constant, controlling the second flow modulation device 238 to increase the flow of the second gas while maintaining the flow of the first gas constant, or controlling both the first and second flow modulation devices 236,238 to change the flow rates of both the first and second gasses to obtain a desired ratio of the first to the second gas in the combined flow thereof, and thus the concentration of the first gas in the combined flow of the first and second gasses.

In another embodiment, a single injector, here a side flowing second injector, here second injector 220a, is provided to extend inwardly of the first conduit 202 just inwardly thereof from the second end 208 thereof, and as shown in FIG. 7, includes therein a single, gas injection opening 222, in the aspect shown in FIG. 7, flowing the second gas as a flow shown by arrows B perpendicular to the flow of the first, activated, gas shown as arrow A flowing in the X direction, and exiting the gas injection opening 222 in a direction directly perpendicular to the flow direction A of the first gas, with the resultant mixed stream of the first and second gas from the remote plasma generator 200 and the side flowing second injector s flowing in the direction of the second conduit 204 and the process chamber 110 as shown by arrow C. This flow then expands in all three directions (the X, Y and Z directions) as it passes through the expanding cross section of the second conduit 204 as shown by arrows C in FIG. 3, and enters the process chamber 110 through the inlet port 80 in the process chamber.

The flow of the second gas in the first conduit 202 in the flow direction B perpendicular to the flow direction A of the first gas coming from the remote plasma generator 200 and flowing within the first conduit 202 toward the inlet port 80 of the process chamber 110 helps ensure sufficient inter-mixing of the second gas with the first gas to ensure sufficient uniformity of the concentration of the first gas in the combined flow of the first and second gas across the substrate upper surface 230 to enable uniform processing of the exposed surface thereof over the entire substrate upper surface.

In another embodiment, a single injector, here an angled opening third injector 220b, is provided to extend inwardly of the first conduit 202 at a location in the X direction just inwardly thereof from the second end 208 thereof, and as shown in FIG. 8 includes therein a single, gas injection opening 222, here extending downwardly, initially in the Z and X directions from the central gas flow passage 221 of the angled opening third injector 220b in the aspect shown in FIG. 8, flowing the second gas as a flow shown by arrows B as it exits the gas injection opening 222 at flow direction of arrow B initially at an angle of approximately 45° but not limited to in the X-Z direction to the flow direction of arrow A of the first, activated, gas flowing in the X direction and in the same, with the resultant mixed stream of the first and second gas flowing in the direction of the second conduit 204 and process chamber 110 as shown by arrow C. This flow then expands in all directions (the X, Y and Z directions) as it passes through the expanding cross section of the second conduit 204 as shown by arrows C in FIG. 3, and enters the process chamber 110 through the inlet port 80.

The flow of the second gas in the first conduit 202 in the flow direction A of flow of the first gas coming from the remote plasma generator 200 and flowing within the first conduit 202 toward the inlet port 80 of the process chamber 110, as well as across the flow direction A in the z direction, helps ensure sufficient inter-mixing of the second gas with the first gas to ensure sufficient uniformity of the concentration of the first gas in the combined flow of the first and second gas across the substrate upper surface 230 to enable uniform processing of the exposed surface thereof over the entire substrate upper surface 230.

In another embodiment, a single injector, here a double opening fourth injector 220c is provided to extend inwardly of the first conduit 202 just inwardly thereof from the second end 208 thereof, and as shown in FIG. 9 includes therein a duality of gas injection openings 222a, b extending outwardly thereof from the central gas flow passage 221 in which a first gas injection opening 222a is directly below a second gas injection opening 222b, and the flow directions of gas therein reaching the exit of the gas injection openings 222a, b are parallel to one another, and as a flow shown by arrows B, initially perpendicular to the flow of the first, activated, gas shown as arrow A with the resultant mixed stream of the first and second gas from in the direction of the second conduit 204 as shown by arrow C. This flow then expands in all directions (the X, Y and Z directions) as it passes through the expanding cross section of the second conduit 204 as shown by arrows C in FIG. 3, and enters the process chamber 110 through the inlet port 80.

The flow of the second gas in the first conduit 202 in the direction of arrow B perpendicular to the flow direction of arrow A of the first gas coming from the remote plasma generator 200 and flowing within the first conduit 202 toward the inlet port 80 of the process chamber 110 helps ensure sufficient inter-mixing of the second gas with the first gas to ensure sufficient uniformity of the concentration of the first gas in the combined flow of the first and second gas across the substrate upper surface 230 to enable uniform processing of the exposed surface thereof over the entire substrate upper surface 230.

In another embodiment, a single injector, here a dual opening upstream directed fifth injector 220d is provided to extend inwardly of the first conduit 202 at a location just inwardly thereof from the second end 208 thereof, and as shown in FIG. 10 includes therein a duality of gas injection openings 222a, b in which the first gas injection opening 222a is directly below the second gas injection opening 222b and in the same plane, i.e., they are directed parallel to one another and in the same direction, in the aspect shown in FIG. 10, flowing the second gas as a flow shown by arrows B into, or at 0°, in the X-Z direction with respect to the flow of the first, activated, gas shown as arrow A, in the directly upstream direction of the flow of the first gas, with the resultant mixed stream of the first and second gas from in the direction of the second conduit 204 as shown by arrow C. This flow then expands in all directions (the X, Y and Z directions) as it passes through the expanding cross section of the second conduit 204 as shown by arrows C in FIG. 3, and enters the process chamber 110 through the inlet port 80.

The flow of the second gas outwardly of the gas injection openings 222 thereof and into the first conduit 202 in a flow direction which is variable in a direction B leaving the outlet of between 0° to 360° to the flow direction A of the first gas coming from the remote plasma generator 200 and flowing within the first conduit 202 toward the inlet port 80 of the process chamber 110 helps ensure sufficient inter-mixing of the second gas with the first gas to ensure sufficient uniformity of or homogenization of the concentration of the first gas in the combined flow of the first and second gas across the substrate upper surface 230 to enable uniform processing of the exposed surface thereof over the entire substrate upper surface 230.

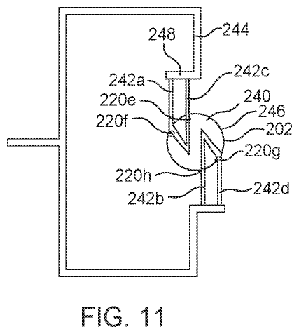

In another aspect hereof, a plurality of injectors, here inline injectors 242a-d having a single opening extending from the inner gas channel 244 thereof and through the outer wall 246 of the inline injector 242a-d at the tip end 248 thereof are provided to extend inwardly of the first conduit 202 and slightly inwardly of the inner wall 240 thereof, such that a flow of the second gas is provided therefrom and into the first conduit 202 from each at an angle of between 0 and 90 degrees with respect to the adjacent surface of the inner wall 240 of the first conduit 202, and also perpendicular to the flow direction A of the flow of the first gas within the first conduit 202, causing the second gas to be injected in a direction tangent to imaginary circles within the first conduit and creating a swirling flow pattern locally in the first conduit 202, while the combined flow of the first and second gases continues to flow in the flow direction C and into the second conduit 204 and the process chamber 110. As shown in FIG. 11 a first pair of gas injectors 220e, f are provided 180° from the second pair of gas injectors 220g, h about the circumference of the first conduit 202 with the resultant mixed stream of the first and second gas flowing therefrom toward and into the second conduit 204. This flow then expands in all directions (the X, Y and Z directions) as it passes through the expanding cross section of the second conduit 204 as shown by arrows C in FIG. 3, and enters the process chamber 110 through the inlet port 80.

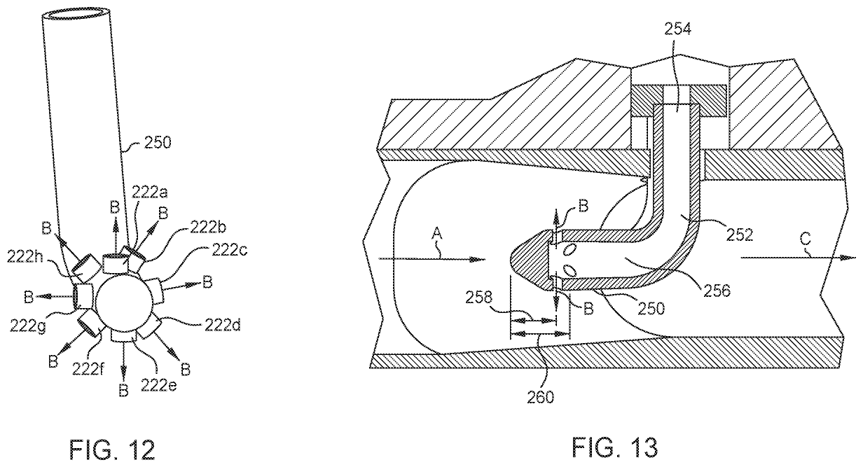

In another embodiment, a single injector, here a flow coaxial injector 250, is provided and includes a coaxial injector body 252 having a first portion 254 extending inwardly of the inner wall of the first conduit 202 and perpendicular to the flow of the first gas A within the first conduit 202 at a location just inwardly thereof from the second end 208 thereof, and a second portion 256 extending from the first portion 254 at an angle of 90° and in the upstream direction of flow direction A of the first gas and generally centered in the first conduit 202. As shown in FIG. 13, the flow coaxial injector 250 includes therein a plurality of gas injection openings 222, the openings spaced at 90 degree intervals from one another about the outer circumference of the second portion and in two lateral locations from the tip end of the second portion 256, i.e., four openings; 222a, 222c, 222e and 222g are spaced at 90 degrees from one another about the outer circumference of the second portion 256 at a first lateral distance 258 from the tip end of the second portion 256, and four openings; 222b, 222d, 222f and 222h) are spaced at 90 degrees from one another about the outer circumference of the second portion 256 at a second lateral distance 260 from the tip end of the second portion 256. FIG. 12 is a gas presence view of the gas passages within the flow coaxial injector 250, showing the location of the gas within the injector with the wall surfaces thereof removed, to better show the multiple gas injection openings 222. Each of the openings 222a-h are oriented to release the second gas therefrom in a flow direction B perpendicular to the flow direction A of the first gas, to intermix the first and second gases as shown by arrows B showing the flow of the second gas into the flow of the first, activated, gas shown as arrow A with the resultant mixed stream of the first and second gas flows from in the direction of the second conduit 204 as shown by arrow C. This combined inter mixed flow then expands in all directions (the X, Y and Z directions) as it passes through the expanding cross section of the second conduit 204 as shown by arrows C in FIG. 3, and enters the process chamber 110 through the inlet port 80.

The mixed flow of the first and second gasses then flows over a substrate 32 supported on, and rotated about the center point 224 of the rotor 26, in either a clockwise direction 226 or counterclockwise direction 228 (looking down on the rotor from the perspective of the lamp assembly 16), whereby the mixed flow of gasses is distributed over the entire substrate upper surface 230. The substrate upper surface 230 is rotated, when supported on the rotor 26 and the rotor 26 is magnetically levitating and rotating about the center point 224 at an elevation, with respect to the surface of the earth, which is slightly below the lower wall 214 of the second conduit, and both extend generally horizontally, and in parallel planes, to one another. Thus, as the mixed flow C of the first and second gasses flows inwardly of the inlet port 80, it is injected inwardly from the inlet over the substrate upper surface 230, at least beyond the center point 224 of the rotor 26, and thus gas introduction paradigm, in conjunction with the rotation of the substrate 32, causes the mixed flow C of the first and second gasses to reach all locations of the substrate upper surface 230 to react therewith.

The flow of the second gas in the first conduit 202 in the flow direction B perpendicular of the flow direction A of the first gas coming from the remote plasma generator 200 and flowing within the first conduit 202 toward the inlet port 80 of the process chamber 110 helps ensure sufficient inter-mixing of the second gas with the first gas to ensure sufficient uniformity of the concentration of the first gas in the combined flow of the first and second gas across the substrate upper surface 230 to enable uniform processing of the exposed surface thereof over the entire substrate upper surface.

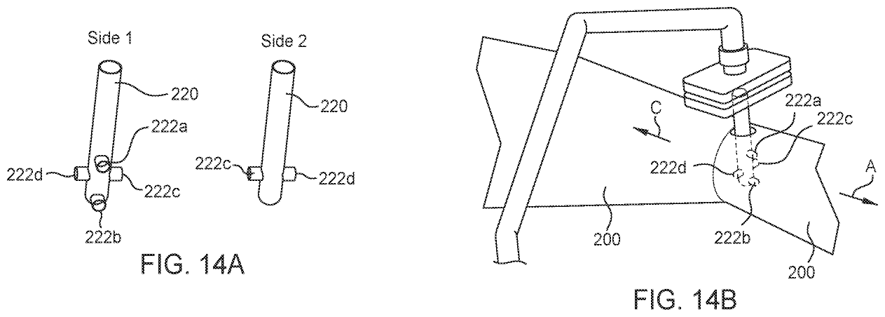

In another aspect, in this aspect a single injector configured as a 3-axis first injector 220 is provided to extend inwardly of the first conduit 202 just inwardly thereof from the second end 208 thereof, and as shown in FIG. 14B includes therein a plurality of gas injection openings 222 in which a set of gas injection openings 222a, b are provided to direct the second gas therefrom initially at an angle of 180° to the direction of flow of the first gas flow A, and the first gas injection opening 222a is directly above the second gas injection opening 222b in the same plane, and individual openings 222c, 222d are provided to direct the second gas therefrom initially at 90° and 270° to the flow direction A of the first gas, in which flowing the second gas into the flow of the first, activated, gas in the direction directly upstream of the flow of the first gas, with the resultant mixed stream of the first and second gases flowing in the direction of the second conduit 204 as shown by arrow C. This flow then expands in all directions (the X, Y and Z directions) as it passes through the expanding cross section of the second conduit 204 as shown by arrows C in FIG. 3, and enters the process chamber 110 through the inlet port 80.

The mixed flow of the first and second gasses then flows over a substrate 32 supported on, and rotated about the center point 224 of the rotor 26, in either a clockwise direction 226 or counterclockwise direction 228 (looking down on the rotor from the perspective of the lamp assembly 16), whereby the mixed flow of gasses C is distributed over the entire surface of the substrate 32. The substrate upper surface 230 is rotated, when supported on the rotor 26 and the rotor 26 is magnetically levitating and rotating about the center point 224 at an elevation, with respect to the surface of the earth, which is slightly below the lower wall 214 of the second conduit, and both extend generally horizontally, and in parallel planes, to one another. Thus, as the mixed flow C of the first and second gasses flows inwardly of the inlet port 80, it is injected inwardly from the inlet over the substrate upper surface 230, at least beyond the center point 224 of the rotor 26, and thus gas introduction paradigm, in conjunction with the rotation of the substrate 32, causes the mixed flow C of the first and second gasses to reach all locations of the substrate upper surface 230 to react therewith.

The flow of the second gas in the first conduit 202 initially in the direction between 90° to 270° of the flow direction A of the first gas coming from the remote plasma generator 200 and flowing within the first conduit 202 toward the inlet port 80 of the process chamber 110 helps ensure sufficient inter-mixing of the second gas with the first gas to ensure sufficient uniformity of the concentration of the first gas in the combined flow of the first and second gases across the substrate upper surface 230 to enable uniform processing of the exposed surface thereof over the entire substrate upper surface 230.

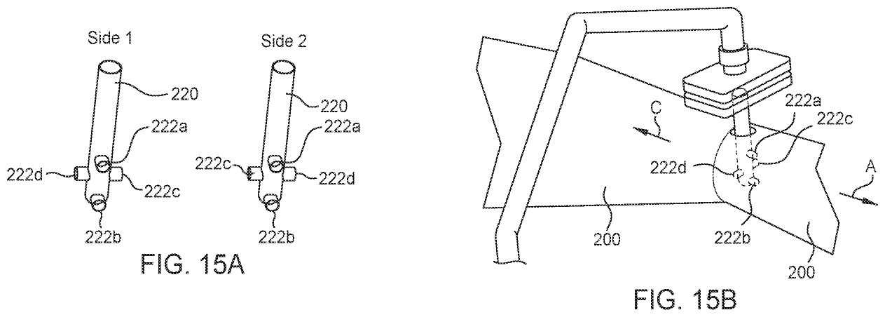

In another aspect, in this aspect a single or first injector 220 is provided to extend inwardly of the first conduit 202 just inwardly thereof from the second end 208 thereof, and as shown in FIG. 15B includes therein a plurality of gas injection openings 222 in which a set of two openings are provided 0° and 180° to the direction of flow of the first gas, and the first opening in each set is directly below the second opening in the same plane, and individual openings are provided 90° and 270° to the flow direction A of the first gas, as in the aspect shown in FIG. 15A, in which flowing the second gas into the flow of the first, activated, gas shown as arrow A, in the direction directly upstream of the flow of the first gas A, with the resultant mixed stream of the first and second gas from in the direction of the second conduit 204 as shown by arrow C. This flow then expands in all directions (the X, Y and Z directions) as it passes through the expanding cross section of the second conduit 204 as shown by arrows C in FIG. 3, and enters the process chamber 110 through the inlet port 80.

The mixed flow of the first and second gases then flows over a substrate 32 supported on, and rotated about the center point 224 of the rotor 26, in either a clockwise direction 226 or counterclockwise direction 228 (looking down on the rotor from the perspective of the lamp assembly 16), whereby the mixed flow of gases is distributed over the entire surface of the substrate 32. The substrate upper surface 230 is rotated, when supported on the rotor 26 and the rotor 26 is magnetically levitating and rotating about the center point 224 at an elevation, with respect to the surface of the earth, which is slightly below the lower wall 214 of the second conduit, and both extend generally horizontally, and in parallel planes, to one another. Thus, as the mixed flow C of the first and second gasses flows inwardly of the inlet port 80, it is injected inwardly from the inlet over the substrate upper surface 230, at least beyond the center point 224 of the rotor 26, and thus gas introduction paradigm, in conjunction with the rotation of the substrate 32, causes the mixed flow of the first and second gases to reach all locations of the substrate upper surface 230 to react therewith.

The flow of the second gas in the first conduit 202 in the direction 0°, 90°, 180° and 270° of the flow direction A of the first gas coming from the remote plasma generator 200 and flowing within the first conduit 202 toward the inlet port 80 of the process chamber 110 helps ensure sufficient inter-mixing of the second gas with the first gas to ensure sufficient uniformity of the concentration of the first gas in the combined flow C of the first and second gas across the substrate upper surface 230 to enable uniform processing of the exposed surface thereof over the entire substrate upper surface 230.

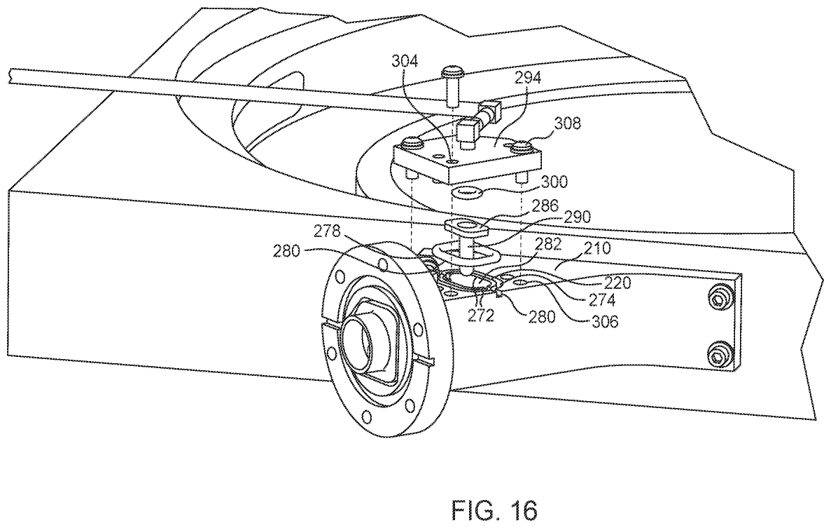

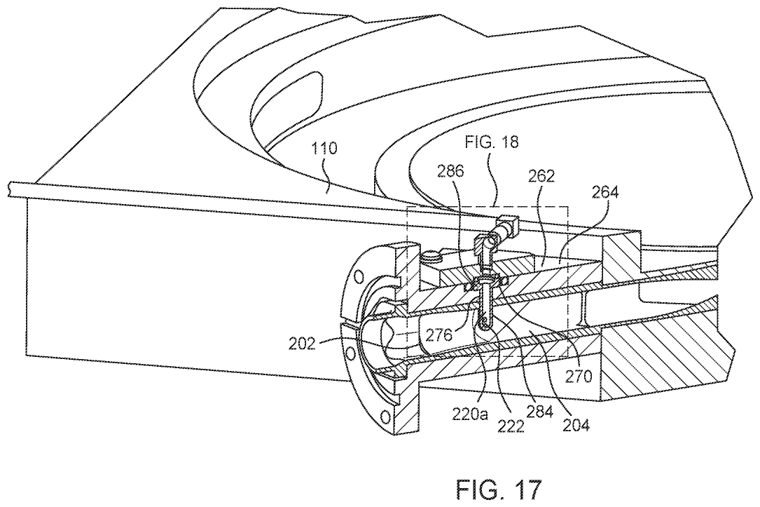

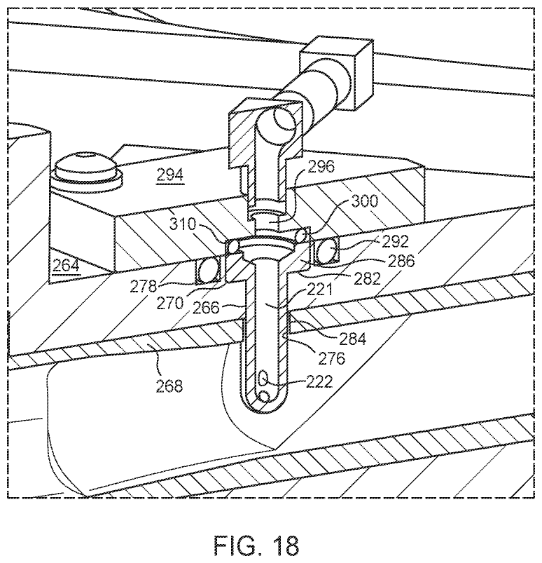

To position an injector, for example, second injector 220a of FIG. 7 such that the gas injection opening 222 to inject the second gas is positioned within the interior of the first conduit 202, a sealable opening is required. Referring to FIGS. 16 to 18, one construct of such a sealed opening is shown, wherein a sleeve 262 is coupled over, and surrounding, the first and second conduit 202, 204, and includes thereon a generally flat outer surface 264 through which the tip end of the second injector 220a extends into the interior volume of the first conduit. A first injector bore 266 extends inwardly of the inner surface 268 of the sleeve 262, and a recess 270 extends inwardly of the outer surface 264, such that the first injector bore 266 opens in the center of the recess 270. Here, recess 270 is generally rectangular in plan view, and includes four generally flat walls 272, each connected to an adjacent flat wall by one of four curved walls 274. A retainer ledge 283 is thus formed which extends as the base of the recess 270 from the terminus of the first injector bore 266 thereat to the surrounding generally flat and curved walls 272, 274. A second injector bore 276 extends through the wall of the first conduit 202 in alignment with the first injector bore 266. An annular seal recess 278 extends inwardly of the outer surface 264 of the sleeve 262, and surrounds the recess 270. Relief slots 280 extend from opposed sides of the annular seal recess 278.

Second injector 220a includes a shank portion 284, through the center of which extends the central gas flow passage 221 and through which gas injection opening 222 extends, and a head portion 286 having a generally rectangular profile with four outer walls 288 and four connecting rounded outer walls 290, such that the shank portion 284 extends from the head portion 286, and the head portion 286 is receivable within the recess 270, such that the gas injection opening 222 of the shank portion 284 is positioned within the interior or the first conduit 202.

A cover plate 294 is provided, and includes therein an injector flow passage 296 connected to a gas line 298, and is positionable over the head portion 286 of the second injector 220a to secure the head portion 286 in the recess 270. To seal the connection of the injector into the first conduit 202, a first seal ring 292, for example an O-ring having a width in section greater than the depth of the annular seal recess 278 is located in the annular seal recess 278, and a second seal ring 300 is located over the head portion 286 of the second injector 220a, and surrounding the opening of the central gas flow passage 221 therethrough, and the cover plate 294 is located over the second seal ring 300 and the outer surface 264 of the sleeve 262, and secured to the sleeve 262, such that the injector flow passage 296 thereof is centered over the central gas flow passage 221 of the second injector 220a. Here, to secure the cover plate 294 to the sleeve 262, the cover plate includes a plurality of, here four, through holes 304 generally located at corners of the plate 294, the sleeve 262 includes four threaded openings 306 extending inwardly of the upper surface thereof outwardly of the annular seal recess 278, and threaded fasteners 308 extend through the through holes 304 and are threaded into the threaded openings 306 to secure the cover plate 294 in place. Cover plat also includes, on the sleeve facing surface side thereof, a generally circular counterbore, here counterbore 310 extending inwardly thereof, into which a portion of the second seal ring 300 is received. Thus, with the cover plate 294 secured in place, the first seal ring contacts, and seals against, the surface of the annular seal recess 278 and the sleeve facing surface of the cover plate 294, and the second seal ring contacts, and seals against, the upper surface of the head portion 286 and the annular surface of the base of the counterbore 310 surrounding the injector flow passage 296, together sealing off the gas flowing into the second injector 220a form the surrounding ambient.

To properly align the initial flow direction of the gas leaving an injector opening, two of the four generally flat walls 272 of the recess which are parallel to one another, i.e., face each other across the recess 270, have a different length than the other two of the four generally flat walls 272. Thus, if the orientation of the gas injection opening 222 of the first injector 220 is selected relative to the matching rectangular head portion, here head portion 286, walls, the direction of the gas injection opening 222, relative to the gas flow direction, can be preset by design. To ensure the direction, for example upstream or downstream, or to the right or to the left, of the flow direction of the first gas species in the first conduit, a key feature, such as a tab or other protrusion may be located on the head portion, and a corresponding cutout or key way can be provided at the recess.

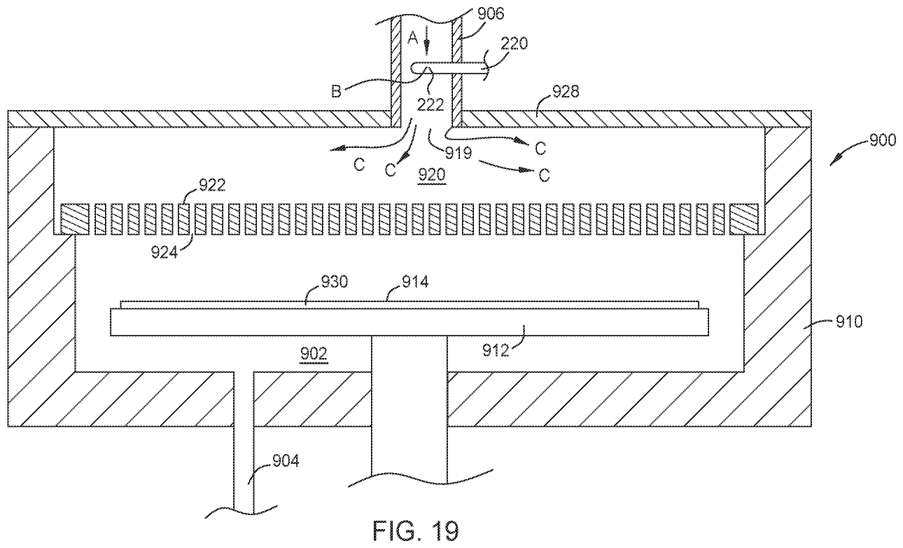

FIG. 19 shows a chamber 900 suitable for performing processes such as chemical vapor deposition (CVD) or etching on a large substrate. The chamber has a housing or chamber wall 910, preferably composed of metal that encircles the interior of the chamber. The chamber wall 910 provides the vacuum enclosure for the side, and much of the bottom, of the chamber interior. A pedestal or susceptor 912 functions as a substrate support and has a flat upper surface that supports a workpiece or substrate 914 thereon. Alternatively, the substrate need not directly contact the susceptor, but may be held slightly above the upper surface of the susceptor by, for example, a plurality of lift pins, not shown.

An external gas supply delivers one or more process gases to the process chamber. Specifically, the chamber here includes and includes a gas inlet manifold or plenum 920 extending between a gas inlet 918 and a gas diffuser plate of diffuser, commonly known as a showerhead 922. A gas line or primary conduit 906 extending from an external gas supply (not shown) to a gas inlet aperture or 918 in the top wall of the chamber 900 opens into the plenum 920, where they intermix and extend over the entire backside of the showerhead 922 forming the lower wall of the plenum 920. The gases then flow from the plenum 920 through hundreds or thousands of openings 924 in the showerhead 922 so as to enter the region of the chamber interior between the showerhead 922 and the susceptor 912.

A conventional vacuum pump coupled to the interior volume 902 of the chamber 900 through an exhaust 904 maintains a desired level of vacuum within the chamber 900 and exhausts the process gases and reaction products from the chamber 900.

A first gas, after having passed through a remote plasma source or generator, is flowed through the primary conduit 906 and thence inwardly of the plenum 920 through the gas inlet 918, and an injector, here a side flowing second injector, here second injector 220a, is provided to extend inwardly of the primary conduit 906, and it includes therein a single, gas injection opening 222, similar to that shown in FIG. 7, flowing a second gas as a flow shown by arrow B (extending perpendicular to the plane of FIG. 19 and outwardly of the page) perpendicular to the flow of the first, activated, gas shown as arrow A flowing in the X direction, and exiting the gas injection opening 222 in a direction directly perpendicular to the flow direction A of the first gas, with the resultant mixed stream of the first and second gas from the remote plasma generator and the side flowing injector flows into the plenum as shown by arrow C. This flow then expands within the plenum 920 over the entire plenum facing surface of the showerhead 922.

The flow of the second gas in the primary conduit 906 in the flow direction B perpendicular to the flow direction A of the first gas coming from the remote plasma generator and flowing within the primary conduit 906 toward the gas inlet 918 of the chamber 900 helps ensure sufficient inter-mixing of the second gas with the first gas to ensure sufficient uniformity of the concentration of the first gas in the combined flow of the first and second gas across the plenum facing side of the showerhead 922 for delivery to the substrate upper surface 230 through the openings 924 therethrough to enable uniform processing of the exposed surface thereof over the entire substrate upper surface 930.

The first injector 220 extending inwardly of the primary conduit 906 can be configured with one or more gas injection openings therein, to initially direct the second gas flowed therefrom in a direction parallel to and in the downstream flow direction of the first gas flow, in a direction parallel to and in the upstream flow direction of the first gas flow, and in any other direction other than directly inwardly of the injector.

In the various aspects shown herein, the second gas may be diluting gas, an inert gas, or a gas which reacts with the first gas, and may be supplied, where desired, after having itself passed through a remote plasma source.

While the foregoing is directed to embodiments of the present disclosure, other and further embodiments of the disclosure may be devised without departing from the basic scope thereof, and the scope thereof is determined by the claims that follow.

1. A gas source, comprising:
a flow conduit having an interior volume and an open end;
a remote plasma source fluidly coupled to a source of a first gas and to the interior volume of the flow conduit; and
a secondary gas source extending inwardly of the interior volume of the flow conduit, the secondary gas source including at least one gas port therein positioned to flow a secondary gas inwardly of the interior volume of the flow conduit.

2. The gas source of claim 1, wherein the flow conduit includes an expanding portion interposed between the remote plasma source and the open end thereof.

3. The gas source of claim 1, wherein the flow conduit includes an expanding portion interposed between the location of the secondary gas source inwardly of the interior volume of the flow conduit and the open end thereof.

4. The gas source of claim 1, wherein the secondary gas source comprises a gas injector extending inwardly of the interior volume of the flow conduit.

5. The gas source of claim 4, wherein the flow conduit further comprises an upstream side connected to the remote plasma source, and a downstream side; and
the gas injector includes a flow passage therein in fluid communication with the secondary gas source, and at least one gas outlet opening extending from the flow passage and into communication with the interior volume of the flow conduit.

6. The gas source of claim 5, wherein the gas outlet opening is directed toward the upstream side of the flow conduit.

7. The gas source of claim 5, wherein the gas outlet opening is directed toward the downstream side of the flow conduit.

8. The gas source of claim 5, wherein the at least one gas outlet includes a first gas outlet and a second gas outlet, wherein the first gas outlet and the second gas outlet are directed toward the upstream side of the flow conduit.

9. The gas source of claim 5, wherein the at least one gas outlet includes a first gas outlet and a second gas outlet, wherein the gas outlet and the second gas outlet are directed in a direction between the upstream side of the flow conduit and the downstream side of the flow conduit.

10. The gas source of claim 15 wherein the at least one gas outlet includes a first gas outlet opening and a second gas outlet opening, wherein the first gas outlet opening is directed toward the upstream side of the flow conduit, and the second gas outlet opening is directed toward the downstream side of the flow conduit.

11. The gas source of claim 1, wherein the secondary gas source includes a first portion extending through the wall of the flow conduit, and a second portion, extending from the first portion at an angle of 85 to 105 degrees with respect to the direction of the first portion, and the at least one gas outlet is disposed in the second portion.

12. A method of providing a mixture of a first gas and a second gas into a process chamber having a chamber inlet, comprising;
providing a conduit, having an internal flow volume, a first end and a second end, wherein the second end of the flow conduit is connected to the chamber inlet;
providing a plasma source in fluid communication with the first end of the flow conduit, the plasma source configured to activate at least a portion of a first gas species flowing therethrough into radicals of the gas species;
extending an injector, having at least one injector opening, inwardly of the flow conduit at a location intermediate of the first end and the second end of the flow conduit, the injector opening in fluid communication with the flow volume of the flow conduit.

13. The method of claim 13, wherein the flow conduit includes a first portion and a second portion, wherein the second portion extends from the first portion toward the second end of the flow conduit, and the interior volume of the second portion increase in the direction thereof toward the second end of the flow conduit.

14. The method of claim 13, wherein the at least one injector opening extends in a direction of at least one of from the second end to the first end of the flow conduit, and a direction from the first end to the second end of the flow conduit.

15. The method of claim 13, wherein the at least one injector opening extends in a direction other than a direction of at least one of from the second end to the first end of the flow conduit, and a direction from the first end to the second end of the flow conduit.

16. The method of claim 13, wherein the at least one injector opening includes a plurality of injector openings, and each of the injector openings extend in one of a direction from the second end to the first end of the flow conduit, a direction from the first end to the second end of the flow conduit, and a direction other than a direction of at least one of from the second end to the first end of the flow conduit, and a direction from the first end to the second end of the flow conduit.

17. A process chamber gas source for connection to a gas inlet of a substrate processing chamber, comprising:
a flow conduit having a second end connectable to a process chamber gas inlet, a first end connectable to a first source of gas, and an interior flow volume surrounded by a flow conduit wall; and
an injector, connectable to a second source of gas, extending through the flow conduit wall and into the interior flow volume thereof, the injector having at least one opening configured to direct gas therefrom initially in a first direction.

18. The process chamber gas source of claim 17, wherein the flow conduit includes a first portion and a second portion, wherein the second portion extends from the first portion toward the second end of the flow conduit, and the interior volume of the second portion increase in the direction thereof toward the second end of the flow conduit; and
the at least one injector opening extends in a direction of at least one of from the second end to the first end of the flow conduit, and a direction from the first end to the second end of the flow conduit.

19. The process chamber gas source of claim 17, wherein
the flow conduit includes a first portion and a second portion, wherein the second portion extends from the first portion toward the second end of the flow conduit, and the interior volume of the second portion increase in the direction thereof toward the second end of the flow conduit; and
the at least one injector opening extends in a direction other than a direction of at least one of from the second end to the first end of the flow conduit, and a direction from the first end to the second end of the flow conduit.

20. The process chamber gas source of claim 17, wherein the flow conduit includes a first portion and a second portion, wherein the second portion extends from the first portion toward the second end of the flow conduit, and the interior volume of the second portion increase in the direction thereof toward the second end of the flow conduit; and
the at least one injector opening includes a plurality of injector openings, and each of the injector openings extend in one of a direction from the second end to the first end of the flow conduit, a direction from the first end to the second end of the flow conduit, and a direction other than a direction of at least one of from the second end to the first end of the flow conduit, and a direction from the first end to the second end of the flow conduit.
